(19) United States
(12) Patent Application Publication
(10) Pub. No.: US 2006/0040450 A1
(43) Pub. Date: Feb. 23, 2006

(54) Source/drain structure for high performance sub 0.1 micron transistors

(75) Inventor: Sheng Teng Hsu, Camas, WA (US)

Correspondence Address: SHARP LABORATORIES OF AMERICA, INC, 5750 NW PACIFIC RIM BLVD, CAMAS, WA, 98642, US

(73) Assignee: Sharp Laboratories of America, Inc.

(21) Appl. No.: 10/923,168

(22) Filed: Aug. 20, 2004

(51) Int. Cl. H01L 21/336

(52) U.S. Cl. 438/305

(57) ABSTRACT

An asymmetric transistor structure comprising a gate structure with a drain halo ion implantation region, without any halo ion implantation region source region is provided. Methods of forming a transistor structure are also provided. An angled halo ion implant is preformed at an angle using ions of the same type as the well to form a drain halo ion implantation region, while protecting the source region to avoid forming a source halo region.

### BACKGROUND OF THE INVENTION

The present method relates to transistor structures and methods of forming transistors.

State of the art high angle low energy ion implantation, commonly referred to as halo ion implantation, has been a key to short channel length MOS transistor fabrication. This process involves performing ion implantation of the same polarity impurity as the well doping to prevent channel punch-through at the operating voltage. The halo implantation increases well doping near the surface at both the source and drain lightly doped drain (LDD) regions. Halo implantation would not increase the drain junction capacitance if the implant is shallower than the source drain junction. However, the halo ion implantation does increase the surface channel doping density at the lightly doped source junction. As a result, the source to surface channel potential barrier is increased, and the source injection efficiency is reduced, which may degrade the drive current of the transistor.

Super steep retrograded well structures have also been used in connection with short channel length MOS transistor fabrication. The well of this structure is heavily doped. The well doping density is concentrated toward the surface, and correspondingly toward the channel of the device. The heavily doped well is also designed to stop the channel punch-through effect. The surface doping density is relatively low. The well doping at the n+ to well junction is high. Therefore, the junction capacitance is high, the back bias effect is large and the subthreshold slope is very large, which in turn degrades the speed of the device.

### BRIEF DESCRIPTION OF THE DRAWINGS

FIG. 1 is a cross sectional view of an nMOS transistor structure.

FIG. 2 is a cross sectional view of an intermediate transistor structure.

FIG. 3 is a cross sectional view of an intermediate transistor structure.

FIG. 4 is a cross sectional view of an intermediate transistor structure.

FIG. 5 is a cross sectional view of a pMOS transistor structure.

FIG. 6 is a cross sectional view of a CMOS transistor structure.

### DETAILED DESCRIPTION OF THE INVENTION

Accordingly, asymmetric channel transistor structures are provided, along with methods of fabrication. An asymmetric channel transistor with standard source/drain extensions and n+ and p+ ion implantation, with drain side halo ion implantation may improve one, or more, device properties, such as short channel effect, drain drive current, and drain breakdown voltage. A halo ion implantation refers to a high angle low dose ion implantation.

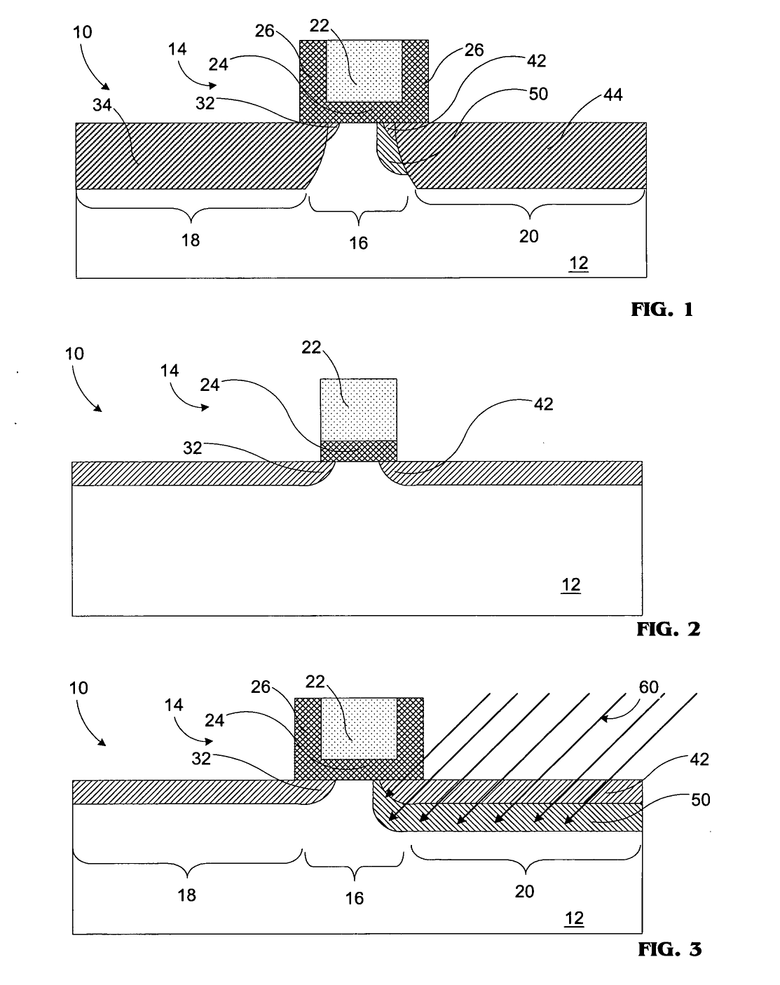

The device structure and the doping profile for an nMOS transistor structure 10 are shown in FIG. 1. The transistor structure 10 comprises a p-well 12 formed within a substrate. A gate structure 14 overlies a channel region 16 interposed between a source region 18 and a drain region 20. The gate structure 14 has a gate electrode 22 overlying a gate dielectric 24 and sidewalls 26 along the sides of the gate 22. The source region 18 has a lightly n-type doped region 32, which may also be referred to as a source extension region, and an n+ region 34, but no source halo region. The drain region 20 has a lightly doped n-type region 42, which may also be referred to as a drain extension region, an n+ region 44, and a p-type drain halo region 50. The drain halo region 50 is a doped region formed by implanting ions into the drain region at an angle The ions implanted to form the drain halo region are of the same type, either p-type or n-type, as the well. The ions implanted to form the drain halo region are not necessarily the same dopants as that used to dope the well. There is no halo implant to the source junction. Accordingly, the source to channel potential barrier is lower than similar symmetrical designs. The efficiency of carrier injection from the source to the channel is higher than similar symmetrical designs. The halo ion implantation at the drain extension region reduces, or eliminates, channel punch-through and short channel effects. The threshold voltage of the device can also be set by the drain halo ion implantation. The resulting effective channel length is very short, i.e. below 0.1 micron. The present structure may achieve a high drain current for a given gate voltage.

Methods are provided to fabricate high performance sub-0.1 micron devices. Standard processes are used to form device isolation structures and a lightly doped well. For example, the doping density of a p-well should yield very low threshold voltage for the nMOS transistor to be produced. A gate stack is then formed overlying the well. The gate stack may have a gate insulator formed using a thermal oxide, a TEOS oxide, an oxynitride, or a high-k dielectric material. The gate electrode may be a polysilicon gate. This polysilicon gate may be used as the final gate electrode, or alternatively the polysilicon gate will be used as a sacrificial gate that will be replaced later, for example by a metal gate.

As shown in FIG. 2, a transistor structure 10 with a p-well 12 has a gate structure 14 overlying the p-well 12. The gate structure comprises a gate dielectric 24 and a gate electrode 22. A source/drain extension implantation is performed to form source extensions 32 and drain extensions 42. For the present nMOS example, an arsenic ion implantation at an energy of between approximately 1 keV and 50 keV and a dose of between approximately 1×10¹⁴/cm² and 1×10¹⁵/cm² is used. This extension ion implantation may be done using plasma immersion with diffusion to ensure sufficient gate to source/drain overlap.

Sidewalls 26 are then formed along the gate stack. The sidewalls may be oxide sidewalls or nitride sidewalls. The thickness of the sidewall is between approximately 10 nm and 50 nm and may depend on the desired channel length of the device. The sidewall should have good step coverage to provide a straight and uniform thickness for the sidewall of the gate stack. As shown in FIG. 3, the sidewalls are made of the same material as the gate insulator. Alternatively, they may be a different material than the gate insulator. Once the sidewalls are formed, a drain halo ion implantation is performed to implant ions 60 and form the drain halo region 50. For our nMOS example, boron or indium ions are used. The tilt angle during drain halo ion implantation is between approximately 20° and 60° relative to the normal. The dose is between approximately 1×10¹³/cm² and 1×10¹⁴/cm². If boron is used, the ions are implanted at an energy of between approximately 5 keV and 40 keV. Alternatively, if indium is used the ions are implanted at an energy of between approximately 50 keV and 400 keV. The depth of the drain halo ion implantation is preferably deeper than the depth of the preceding extension implantation, but shallower than the subsequent n+ junction. Photoresist (not shown) may be used to ensure that there is no source halo implantation.

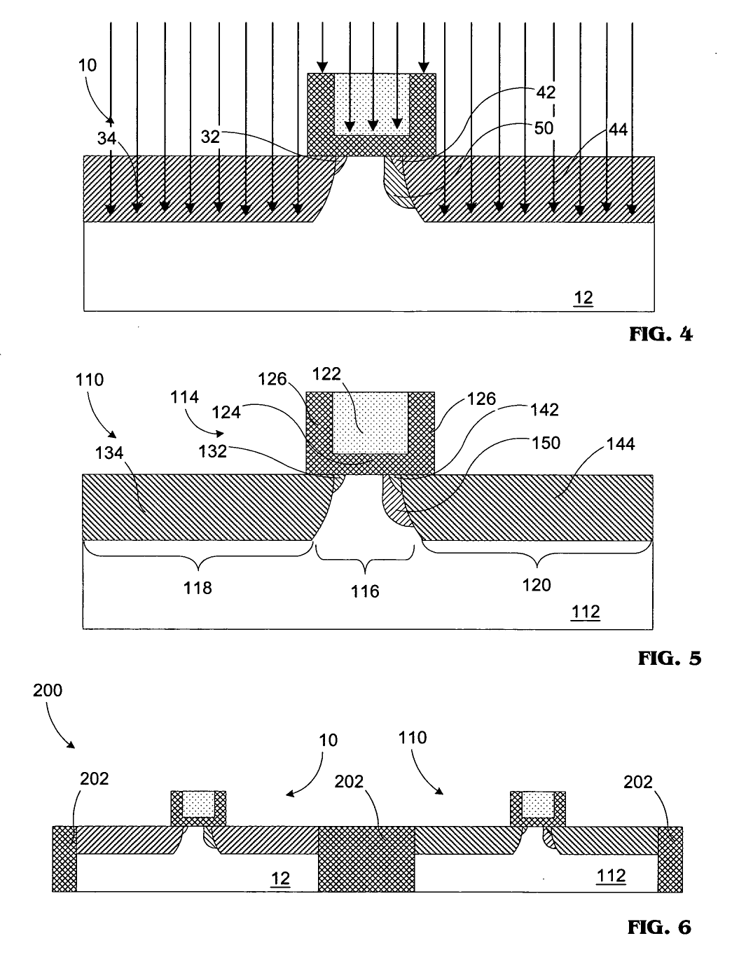

A standard n+ source/drain ion implantation is then performed using any suitable process, as shown in FIG. 4. The ion implantation should be deeper than that of the drain halo ion implantation.

Annealing, passivation, and metallization may then be performed to produce a complete transistor. If the polysilicon gate electrode was being used as a sacrificial gate, a replacement gate process may be used at this point to remove the polysilicon and replace the gate with a different material, for example a metal gate.

The process described above forms an nMOS transistore structure 10. A similar process may be used to produce a pMOS structure. An n-well would be formed. The source/drain extension ion implantation for a pMOS structure would use boron ions at an energy of between approximately 2 keV and 15 keV at a dose of between approximately 1×10¹⁴/cm² and 1×10¹⁵/cm². Alternatively, indium ions may be used at an energy of between approximately 20 keV and 80 keV at a dose of between approximately 1×10¹⁴/cm² and 1×10¹⁵/cm². The sidewalls would be approximately the same thickness. The drain halo ion implantation would use phosphorous ions or arsenic ions at a title angle between approximately 20° and 60° relative to normal incidence. The dose is between approximately 1×10¹³/cm² and 1×10¹⁴/cm². If phosphorous is used, the ions are implanted at an energy of between approximately 10 keV and 100 keV. Alternatively, if arsenic is used the ions are implanted at an energy of between approximately 20 keV and 200 keV. The drain halo ion implantation is preferably deeper than the source/drain extension ion implantation, but shallower than the subsequent p+ junction.

The device structure and the doping profile for a pMOS transistor structure 110 are shown in FIG. 5. The transistor structure 110 comprises an n-well 112 formed within a substrate. A gate structure 114 overlies a channel region 116 interposed between a source region 118 and a drain region 120. The gate structure 114 has a gate electrode 122 overlying a gate dielectric 124 and sidewalls 126 along the sides of the gate 122. The source region 118 has a lightly p-type doped region 132, which may also be referred to as a source extension region, and an p+ region 134, but no source halo region. The drain region 120 has a lightly doped p-type region 142, which may also be referred to as a drain extension region, a p+ region 144, and an n-type drain halo region 150. The drain halo region 150 is a doped region formed by implanting ions into the drain region at an angle The ions implanted to form the drain halo region are not necessarily the same dopants as that used to dope the well. There is no halo implant to the source junction.

FIG. 6 illustrates a CMOS structure 200 comprising an nMOS transistor structure 10 formed in proximity to a pMOS transistor structure 110. The nMOS transistor structure 10 is formed over a p-well separated from the n-well that supports the pMOS transistor structure 110 by isolation regions 202. To form the CMOS 200, a layer of photoresist (not shown) may be deposited to protect the nMOS transistor structure 10 during both the drain halo ion implantation and the source/drain ion implantation of the pMOS transistor structure 110. Similarly, a layer of photoresist may be deposited to protect the pMOS transistor structure 110 during both the drain halo ion implantation and the source/drain ion implantation of the nMOS transistor structure 10. The additional photoresist layers will be removed prior to proceeding with subsequent steps.

what is claimed is:

1. A method of forming a transistor structure comprising:
providing a substrate with an isolated well;
forming a gate stack overlying the substrate;
performing a source/drain extension ion implant;
forming sidewalls;
performing a drain halo ion implant without performing a source halo ion implant; and
performing a source/drain ion implant.

2. The method of claim 1, further comprising depositing and patterning photoresist to prevent ion implantation into the source region.

3. The method of claim 1, wherein the halo ion implant is performed at a tilt angle of between about 20 degrees and about 60 degrees relative to normal incidence.

4. The method of claim 1, wherein performing the drain halo ion implant implants ions are of the same type as the well.

5. The method of claim 1, wherein performing the drain halo ion implant implants p-type ions into a p-well.

6. The method of claim 5, wherein the p-type ions are boron or indium.

7. The method of claim 6, wherein the p-type ions are implanted to a dose of between approximately 1×10¹³/cm² and 1×10¹⁴/cm².

8. The method of claim 7, wherein boron ions are implanted at an implant energy of between approximately 5 keV and 40 keV.

9. The method of claim 7, wherein indium ions are implanted at an implant energy of between approximately 50 keV and 400 keV.

10. The method of claim 1, wherein performing the drain halo ion implant implants n-type ions into an n-well.

11. The method of claim 10, wherein the n-type ions are phosphorous or arsenic.

12. The method of claim 11, wherein the n-type ions are implanted to a dose of between approximately 1×10¹³/cm² and 1×10¹⁴/cm².

13. The method of claim 12, wherein phosphorous ions are implanted at an implant energy of between approximately 10 keV and 100 keV.

14. The method of claim 12, wherein arsenic ions are implanted at an implant energy of between approximately 20 keV and 200 keV.

15. A transistor structure comprising a gate structure overlying a channel region interposed between a source region and a drain region within a doped well; wherein the drain region comprises a drain halo ion implantation region, and the source region does not include a halo ion implantation region.

16. The transistor structure of claim 15, wherein the drain halo ion implantation region is the same type as the well type.

17. The transistor structure of claim 15, wherein the drain halo ion implantation region is p-type and the well is p-type.

18. The transistor structure of claim 15, wherein the drain halo ion implantation region is n-type and the well is n-type.

19. The transistor structure of claim 15, wherein the drain region further comprises a drain extension region the opposite type as the well type and is shallower than the drain halo ion implantation region.

20. The transistor structure of claim 15, wherein the drain region further comprises a drain implant that is deeper than the drain halo ion implantation region.

21. The transistor structure of claim 15, wherein the drain region comprises a shallow n-type drain extension region, a p-type drain halo ion implantation region and an n+ drain region.

22. The transistor structure of claim 15, wherein the drain region comprises a shallow p-type drain extension region, an n-type drain halo ion implantation region and an p+ drain region.
